(19) United States
(12) Patent Application Publication
(10) Pub. No.: US 2019/0237132 A1
(43) Pub. Date: Aug. 1, 2019

(54) SEMICONDUCTOR DEVICE PERFORMING ROW HAMMER REFRESH OPERATION

(71) Applicant: MICRON TECHNOLOGY, INC., BOISE, ID (US)

(72) Inventor: Masaru Morohashi, Hachioji (JP)

(73) Assignee: MICRON TECHNOLOGY, INC., BOISE, ID (US)

(21) Appl. No.: 15/884,192

(22) Filed: Jan. 30, 2018

(51) Int. Cl. G11C 11/406; G11C 11/4091; G11C 11/4076; G06F 3/06; G11C 7/02

(52) U.S. Cl. CPC G11C 11/40615; G11C 11/40611; G11C 11/4091; G11C 7/02; G06F 3/0619; G06F 3/0659; G06F 3/0673; G11C 11/4076

(57) ABSTRACT

Disclosed herein is an apparatus that includes a memory cell array including a normal memory region assigned to first value of a redundant signal and a redundancy memory region assigned to a second value of the redundant signal; a first circuit configured to receive a row address signal, produce the first value of the redundant signal if the first circuit detects that the row address signal is inconsistent to any of redundancy information, and produce the second value of the redundant signal and additional row address signal if the first circuit detects that the row address signal is consistent to any of the redundancy information; and a second circuit configured to produce further additional row address signal based on the row address signal and the first value of the redundant signal or based on the additional row address signal and the second value of the redundant signal.

### BACKGROUND

In a semiconductor device such as a DRAM (Dynamic Random Access Memory), when row access is concentrated on the same word line, there is a case where the information retention capacity of memory cells being connected to word lines adjacent to the word line is degraded. Therefore, in order not to lose information in the memory cells being connected to the adjacent word lines, an additional refresh operation on these memory cells may be performed in addition to normal refresh operations. Such an additional refresh operation is referred to as “row hammer refresh operation”.

Meanwhile, a defective word line included in a memory cell array is replaced with a spare word line at a manufacturing stage. Therefore, it is not easy to create a logical address of a physically adjacent word line based on the logical address of a word line on which access is concentrated.

### BRIEF DESCRIPTION OF THE DRAWINGS

FIG. 1 is a black diagram of a semiconductor device according to an embodiment of the present disclosure.

FIG. 2 is a block diagram for explaining a configuration of main units of the row address control circuit.

FIG. 3A is a schematic diagram indicating memory mats included in the memory cell array.

FIG. 3B is a schematic diagram indicating the memory mat.

FIG. 4 is a block diagram for explaining a configuration of the row address control circuit according to a modification.

### DETAILED DESCRIPTION

Various embodiments of the present invention will be explained below in detail with reference to the accompanying drawings. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiment disclosed herein are not necessary mutually exclusive, as some disclosed embodiments can be combined with one or more other disclosed embodiments to form new embodiments.

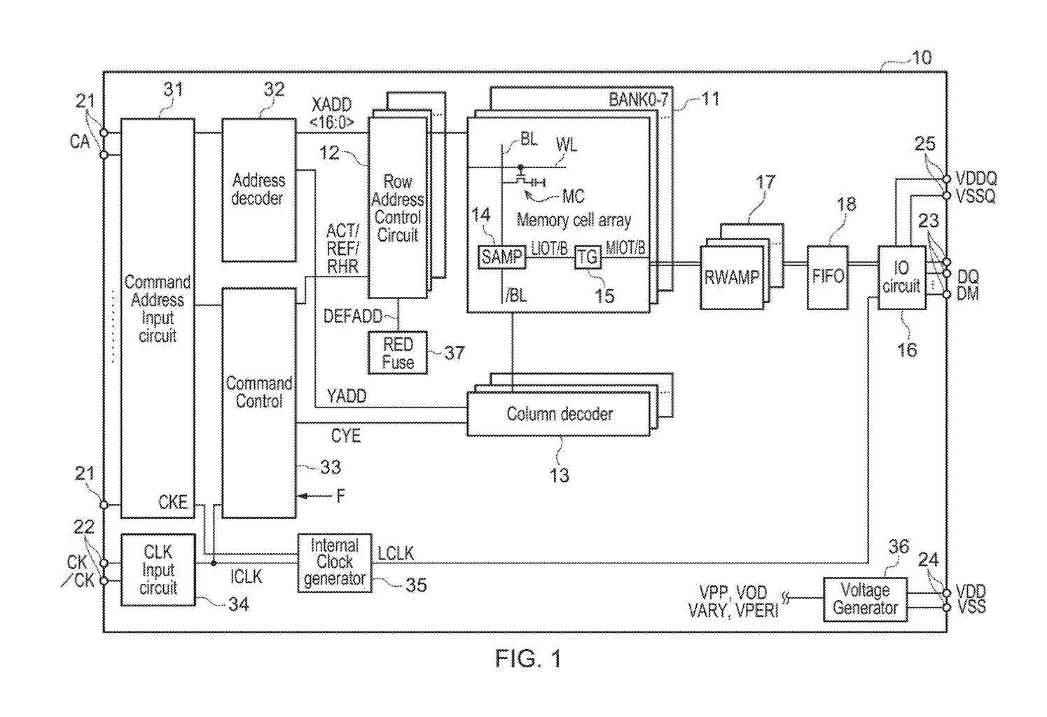

FIG. 1 is a block diagram of the semiconductor device according to an embodiment of the present disclosure. A semiconductor device 10 may be an LPDDR4 SDRAM incorporated in a single semiconductor chip, for example. The semiconductor device 10 may be mounted on an external board, such as a memory module board or a mother board. As illustrated in FIG. 1, the semiconductor device 10 includes a memory cell array 11. The memory cell array 11 includes a plurality of word lines WL, a plurality of bit lines BL, and a plurality of memory cells MC arranged at intersections of the word lines WL and the bit lines BL. Selection of a word line WL is performed by a row address control circuit 12, and selection of a bit line BL is performed by a column decoder 13. A sense amplifier 14 is connected to a corresponding bit line BL and a pair of local I/O lines LIOT/B. The pair of local I/O lines LIOT/B is connected to a pair of main I/O lines MIOT/B via a transfer gate 15 that functions as a switch.

A plurality of external terminals are provided in the semiconductor device 10. The external terminals include command address terminals 21, clock terminals 22, data terminals 23, and power-supply terminals 24 and 25. The data terminals 23 are connected to an I/O circuit 16.

The command address terminal 21 are supplied with a command address signal CA. A portion of the command address CA which relates to an address transferred to an address decodes 32 via a command address input circuit 31. Another portion that relates to a command transferred to a command control circuit 33 via the command address input circuit 31. The address decoder 32 decodes an address signal and generates a row address XADD and a column address YADD. The row address XADD is supplied to the row address control circuit 12, and the column address YADD is supplied to the column decoder 13. Further, a clock enable signal CKE of the command address signal CA is supplied to an internal clock generator 35.

The clock terminals 22 are supplied with complementary external clock signals CK and /CK. The complementary external clock signals CK and /CK are supplied to a clock input circuit 34. The clock input circuit 34 generates an internal clock signal ICLK based on the complementary external clock signals CK and /CK. The internal clock signal ICLK is supplied to at least the command control circuit 33 and the internal clock generator 35. The internal clock generator 35 is activated by the clock enable signal CKE, for example, and generates an internal clock signal LCLK based on the internal clock signal ICLK. The internal clock signal LCLK is supplied to the I/O circuit 16. The internal clock signal LCLK is used as a timing signal that defines a timing at which read data DQ is output from the data terminal 23 at the time of a read operation. In a write operation, write data is input to the data terminal 23 from outside. In the write operation, a data mask signal DM may be input to the data terminal 23 from outside.

The power-supply terminals 24 are supplied with power-supply potentials VDD and VSS. These power-supply potentials VDD and VSS are supplied to a voltage generator 36. The voltage generator 36 generates various internal potentials VPP, VOD, VARY, and VPERI, for example, based on the power-supply potentials VDD and VSS. The internal potential VPP is used mainly in the row address control circuit 12. The internal potentials VOD and VARY are used mainly in the sense amplifier 14 included in the memory cell array 11. The internal potential VPERI is used in many other circuit blocks.

Power-supply potentials VDDQ and VSSQ are supplied to the I/O circuit 16 from the power-supply terminals 25. Although the power-supply potentials VDDQ and VSSQ may be the same potentials as the power-supply potentials VDD and VSS supplied to the power supply terminals 24, respectively, dedicated power-supply potentials VDDQ and VSSQ are assigned to the I/O circuit in order to prevent propagation of power-supply noise generated in the I/O circuit 16 to another circuit block.

The semiconductor device 10 further includes a redundancy fuse circuit 37. In the redundancy (use circuit 37, a row address DEFADD of a defective word line WL is stored in a nonvolatile manner. The row address DEFADD stored in the redundancy fuse circuit 37 is supplied to the row address control circuit 12.

The command control circuit 33 activates an active signal ACT when an active command is issued, and the command control circuit 33 activates a refresh signal REF when a refresh command is issued. When a refresh command is issued in a state where a row hammer refresh operation is necessary, the command control circuit 33 activates a row hammer refresh signal RHR. All of the active signal ACT, the refresh signal REF, and the row hammer refresh signal RHR are supplied to the row address control circuit 12.

When a read command is issued after an active command is issued, the command control circuit 33 activates a column selection signal CYE. The column selection signal CYE is supplied to the column decoder 13, and in response to this operation, read data is read out from the memory cell array 11. The read data read out from the memory cell array 11 is transferred to the I/O circuit 16 via a read/write amplifier 17 and a FIFO circuit 18, and output to outside from the data terminal 23.

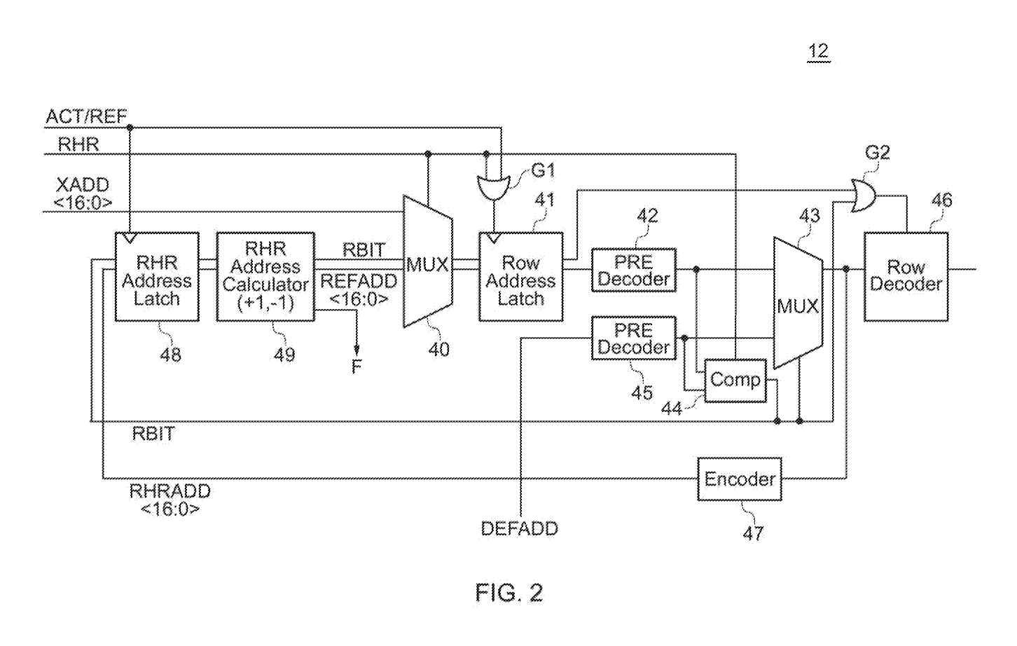

FIG. 2 is a block diagram for explaining a configuration of main units of the row address control circuit 12.

As illustrated in FIG. 2, a row address XADD<16:0> input to the row address control circuit 12 is latched on a row address latch circuit 41 via a multiplexer 40. Although not limited thereto, in the present embodiment, the row address XADD has a 17-bit configuration. The row hammer refresh signal RHR is supplied to the multiplexer 40, and when the row hammer refresh signal RHR is in an inactive state, the multiplexer 40 selects the row address XADD<16:0> having been input to the row address control circuit 12, and supplies the row address XADD<16:0> to the row address latch circuit 45. Meanwhile, the multiplexer 40 selects a raw hammer refresh address REFADD<16:0> output from an address calculator 49, which is described later.

The row address latch circuit 41 performs a latch operation based on an output signal of an OR gate circuit G1. The OR gate circuit G1 has the active signal ACT, the refresh signal REF, and the row hammer refresh signal RHR input therein, so that the latch operation is performed by the row address latch circuit 41 at a timing when any of these signals is activated. An address latched an the row address latch circuit 41 is supplied to a multiplexer 43 and an address comparator 44 via a predecoder 42. The address comparator 44 compares an address output from the predecoder 42 and an address output from a predecoder 45, and activates a bit signal RBIT when the both addresses match each other. The predecoder 45 has supplied thereto the row address DEFADD stored in the redundancy fuse circuit 37. Therefore, when an address output from the row address latch circuit 41 matches the row address DEFADD stored in the redundancy fuse circuit 37, the hit signal RBIT is activated.

The hit signal RBIT is supplied to the multiplexer 43. Subsequently, when the hit signal RBIT is in an inactive suite, the multiplexer 43 selects an original address output from the predecoder 42, and supplies the original address to the row decoder 46. Meanwhile, when the hit signal RBIT is in an active state, the multiplexer 43 selects a replacement address output from the predecoder 45, and supplies the replacement address to the row decoder 46. The row decoder 46 performs row access to the memory cell array 11 based on an input row address <16:0> and a hit signal RBIT supplied via an OR gate circuit G2.

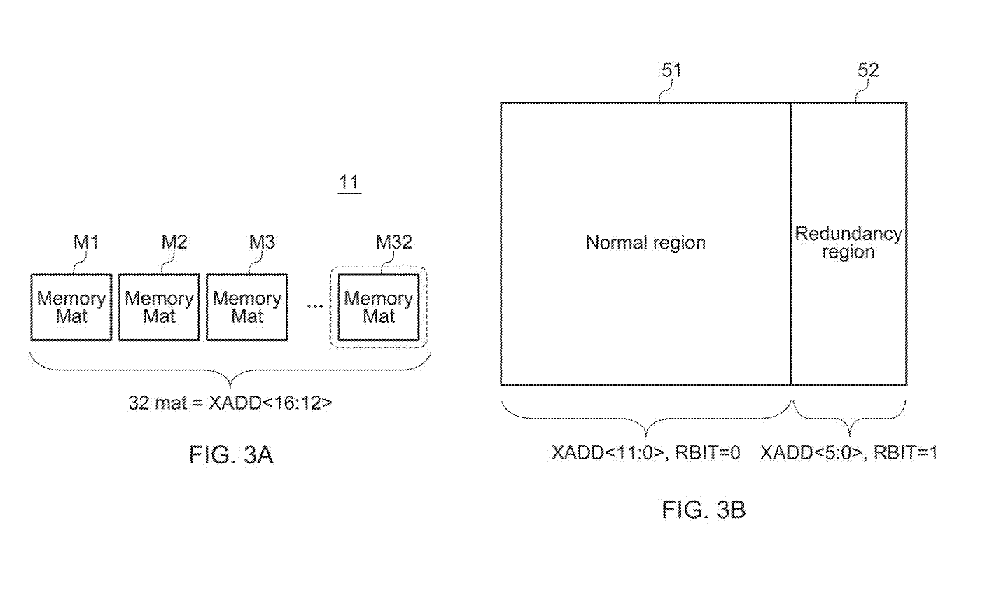

As illustrated in FIG. 3A, a plurality (32, for example) of memory mate M1 to M32 are included in the memory cell array 11. Each of fire memory mats M1 to M32 includes a normal region 51 and a redundancy region 52 illustrated in FIG. 3B. The redundancy region 52 includes spare word lines WL for replacing a defective word line WL among word lines WL included in the normal region 51. The redundancy region 52 is accessed when a replacement address from the predecoder 45 is selected. Meanwhile, when an original address from the predecoder 42 is selected, the normal region 51 is accessed. Specifically, any one of the memory mats M1 to M32 is selected based on an upper 5-bit XADD<16:12> of the row address XADD, and any one of word lines WL belonging to the normal region 51 is selected based on a lower 12-bit XADD<11:0> of the row address XADD. However, when the hit signal RBIT is activated, the access destination is switched to the redundancy region 52, and any one of word lines WL belonging to the redundancy region 52 is selected based on the replacement address. In the example illustrated in FIG. 3B, the significant bit of the replacement address is a lower 6-bit XADD<5:0> of the row address XADD.

As illustrated in FIG. 2, the address output from the multiplexer 43 is converted info a 17-bit row hammer refresh address RHRADD<16:0> by an encoder 47. The row hammer refresh address RHRADD<16:0> is latched on the address latch circuit 48 with the hit signal RBIT. In response to the active signal ACT and the refresh signal REF, the address latch circuit 48 performs a latch operation on the row hammer refresh address RHRADD<16:0> and the hit signal RBIT. As illustrated in FIG. 3B, by using a hit signal RBIT that is not input from outside, the address of the redundancy region 52 as well as that of the normal region 51 can be defined, and an address (a physical address) that covets the entire regions latched on the address latch circuit 48.

The physical address etched on the address latch circuit 48 is supplied to the address calculator 49. The address calculator 49 calculates a physical address of a word line WL that is handled as a subject of a row hammer refresh operation based on the physical address latched on the address latch circuit 48. The word line WL handled as the subject of the row hammer refresh operation is a word line WL that is physically adjacent to an actually accessed word line WL. Therefore, by incrementing (+1) and decrementing (−1) the physical address output from the address latch circuit 48, the address calculator 49 can easily calculate the physical address. The calculated physical address is counted in the address calculator 49, and when the counted value exceeds a predetermined value, a flag F is activated. The flag F is fed back to the command control circuit 33. Upon reception of a refresh command during a period when the flag F is activated, the command control circuit 33 activates the row hammer refresh signal RHR instead of the refresh signal REF.

As described above, the row hammer refresh signal RHR is supplied to the multiplexer 40, and when the row hammer refresh signal RHR is actuated, the row hammer refresh address REFADD<16:0> output, from the address calculator 49 and the hit signal RBIT associated thereto are selected instead of the row address XADD<16:0> supplied from outside, and the selected row hammer refresh address REFADD<16:0> and the selected hit signal RBIT are supplied to the row address latch circuit 41. The row hammer refresh address REFADD<16:0> is supplied to the multiplexer 43 via the predecoder 42, and the hit signal RBIT is supplied to the row decoder 46 via the OR gate circuit G2. At this time, when the row hammer refresh signal RHR is activated, a comparing operation by the address comparator 44 is stopped, and the hit signal RBIT output from the address comparator 44 is fixed in an inactive state. Due to this configuration, the row hammer refresh address REFADD<16:0> output from the predecoder 42 is supplied as it is to the row decoder 46 via the multiplexer 43.

Due to this configuration, when the hit signal RBIT associated with the row hammer refresh address REFADD<16:0> is in an inactive state, that is, when the logic level is 0, the row decoder 46 selects a word line WL belonging to the normal region 51. On the contrary, when the hit signal RBIT associated with the row hammer refresh address REFADD<16:0> is in an active state, that is, when the logic level is 1. the row decoder 46 select a word line WL belonging to the redundancy region That is, when a row hammer refresh operation is performed, the hit signal RBIT is used as an 18th bit (an uppermost bit) of a row address.

In this manner, in the semiconductor device 10 according to the present embodiment, because a physical address of a word line WL on which row access has been actually performed is supplied to the address calculator 49, regardless of whether the word line WL on which row access has been actually performed belongs to the normal region 51 or to the redundancy region 52, by incrementing (+1) and decrementing (−1) a physical address, a physical address of a word line that is handled as a subject of a row hammer refresh operation can be calculated. Further, because the row address of the hit signal RBIT is used as an uppermost bit of a row address, for example, even when the word line WL on which row access has been actually performed is located at an end portion of the normal region 51, that is an actually accessed word line WL is adjacent to a word line WL that is located at an end portion of the redundancy region 52, it is possible to correctly calculate an address of a physically adjacent word line WL without performing any exceptional arithmetic operation.

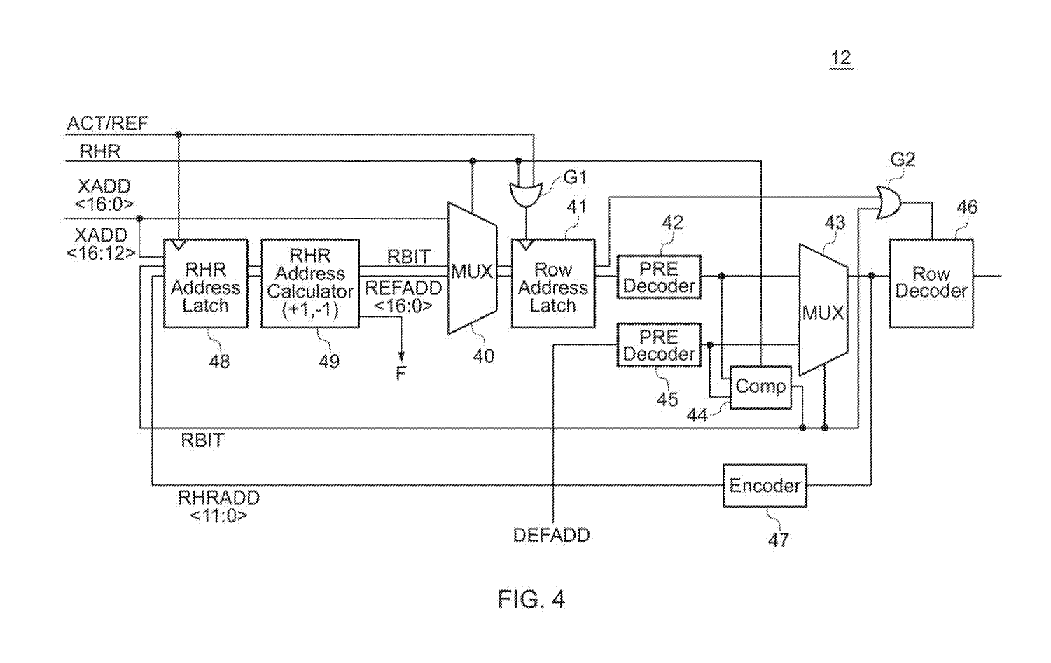

FIG. 4 is a block diagram for explaining a configuration of the row address control circuit 12 according to a modification.

The row address control circuit 12 illustrated in FIG. 4 is different from the row address control circuit 12 illustrated in FIG. 2 in a feature that the row hammer refresh address RHRADD<11:0> output from the encoder 47 is limited to a lower 12-bit and the upper 5-bit XADD<16:12> of the row address XADD supplied from outside is used for an upper 5-bit input to the address latch circuit 48. The difference is made because, as illustrated in FIG. 3A, the upper 5-bit XADD<16.12> of the row address XADD is used to select the memory rams M1 to M32, and as the sense amplifiers 14 are provided between adjacent memory mats, any row hammer refresh operation does not need to be performed for different memory mats. Due to this configuration, it is possible to reduce the number of signal lines in the route from the multiplexer 43 to the address latch circuit 48.

Although his invention has been disclosed in the context of certain preferred embodiments and examples, it will be understood by those skilled in the art that the inventions extend beyond the specifically disclosed embodiments to other alternative embodiments and/or uses of the inventions and obvious modifications and equivalents thereof. In addition, other modifications which are within the scope of this invention will be readily apparent to those of skill in the art based on this disclosure. It is also contemplated that various combination or sub-combination of the specific features and aspects of the embodiments may be made and still fall within the scope of the inventions. It should be understood that various features and aspects of the disclosed embodiments can be combined with or substituted for one another in order to form varying mode of the disclosed invention. Thus, it is intended that the scope of at least some of the present invention herein disclosed should not be limited by the particular disclosed embodiments described above.

1. An apparatus comprising:
a memory cell array including a normal memory region and a redundancy memory region, a plurality of row addresses in the normal memory region being defined, at least in past, with a first value of a redundant signal, and a plurality of row addresses in the redundant memory region being defined, at least in part, with a second value of the redundant signal;
a first circuit configured to receive a row address signal produce the first value of the redundant signal if the first circuit detects that the row address signal is inconsistent to any of redundancy information, and produce the second value of the redundant signal and an additional row address signal if the first circuit detects that the row address signal is consistent to any of the redundancy information; and
a second circuit configured to produce further additional row address signal based on the row address signal and the first value of the redundant signal or based on the additional row address signal and the second value of the redundant signal.

2. The apparatus of claim 1, further comprising a third circuit configured to access the normal memory region based on the row address signal with the first value of the redundant signal, and to access the redundancy memory region based on the additional row address signal with the second value of the redundant signal.

3. The apparatus of claim 2, wherein the third circuit is configured to access the normal memory region based on the further additional row address signal with the first value of the redundant signal.

4. The apparatus of claim 3, wherein the third circuit is configured to access the redundancy memory region based an the further additional row address signal with the second value of the redundant signal.

5. The apparatus of claim 1,
wherein the normal memory region includes first and second word lines physically adjacent to each other,
wherein the first word line is accessed based on the row address signal with the first value of the redundant signal, and
wherein the second word line is accessed based on the further additional row address signal generated based on the row address signal with the first value of the redundant signal.

6. The apparatus of claim 5,
wherein the redundancy memory region includes third and fourth word lines physically adjacent to each other,
wherein the third word line is accessed based on the additional row address signal with the second value of the redundant signal, and
wherein the fourth word line is accessed based on the further additional row address signal generated based on the further additional row address signal with the second value of the redundant signal.

7. The apparatus of claim 6,
wherein the normal memory region further includes a fifth word line, and
the redundancy memory region further includes a sixth word line physically adjacent to the fifth word line.

8. The apparatus of claim 7, wherein the second circuit is configured to produce the further additional row address signal with the second value of the redundant signal related to the sixth word line based on the row address signal with the first value of the redundant signal related to the fifth word line.

9. The apparatus of claim 1, wherein the second circuit is configured to produce the further additional row address signal with the first value of the redundant signal related to the fifth word line based on the row address signal with the second value of the redundant signal related to the sixth word line.

10. The apparatus of claim 1, wherein the second circuit is configured to produce the further additional row address signal by incrementing or decrementing the row address signal with the first value of the redundant signal or the additional row address signal with the second value of the redundant signal

11. An apparatus comprising:
an address terminal configured to receive an input address;
an address storing circuit configured to store a defective address;
an address comparator configured to activate a hit signal when the input address matches with the defective address;
an address converter configured to convert the input address into a spare address when the hit signal is in an active state; and
an address calculator configured to generate a refresh address based on the hit signal and a selected one of the input address and the spare address.

12. The apparatus of claim 11, wherein the address comparator is configured to receive the refresh address instead of the input address when a control signal is activated.

13. The apparatus of claim 12, wherein the address comparator is configured to stop a comparing operation so as not to activate the hit signal when the control signal is activated.

14. An apparatus comprising:
a first memory cell array configured to be assigned with normal addresses;
a second memory cell array configured to be assigned with spare addresses;
an address storing circuit configured to store a defective address included in the normal addresses;
an address comparator configured to activate a hit signal when an input address supplied to an address input node matches with the defective address;
an address selector configured to select the input address when the hit signal is in an inactive state, and select one of the spare addresses when the hit signal is in an active state; and
an address calculator configured to generate a first refresh address based on a selected one of the input address and the one of the spare addresses,
wherein the first refresh address is supplied to the address input node of the address comparator when a first refresh signal is activated, and
wherein the address comparator is configured to stop a comparing operation so as not to activate the hit signal when the first refresh signal is activated.

15. The apparatus of claim 14, wherein the address calculator is configured to generate the first refresh address using the hit signal.

16. The apparatus of claim 15, wherein the hit signal is a most significant bit of the first refresh address.

17. The apparatus of claim 14, wherein the address input node of the address comparator is supplied with a second refresh address when a second refresh signal is activated.

18. The apparatus of claim 17, wherein the first and second refresh signals are exclusively activated.

19. The apparatus of claim 18, wherein the address comparator is configured to perform the comparing operation so as to be able to activate the hit signal when the second refresh signal is activated.

20. The apparatus of claim further comprising a command control circuit configured to activate one of the first and second refresh signals in response to a refresh command issued from an outside of the apparatus.
